(19) United States
(12) Patent Application Publication
(10) Pub. No.: US 2021/0203371 A1
(43) Pub. Date: Jul. 1, 2021

(54) RADIO FREQUENCY MODULE AND COMMUNICATION DEVICE

(71) Applicant: Murata Manufacturing Co., Ltd., Nagaokakyo-shi (JP)

(72) Inventor: Kunitoshi HANAOKA, Nagaokakyo-shi (JP)

(73) Assignee: Murata Manufacturing Co., Ltd., Nagaokakyo-shi (JP)

(21) Appl. No.: 17/124,516

(22) Filed: Dec. 17, 2020

(30) Foreign Application Priority Data
Dec. 25, 2019 (JP) 2019-233728

(51) Int. Cl. H04B 1/40; H01L 23/31; H01L 23/498; H01L 23/66; H01L 23/00

(52) U.S. Cl. CPC H04B 1/40; H01L 23/3185; H01L 23/49816; H01L 23/66; H01L 24/16; H01L 2224/16225; H01L 2924/18161; H01L 2223/6672; H01L 2924/14215; H01L 2924/1206; H01L 2924/1205; H01L 2924/15321; H01L 2223/6655

(57) ABSTRACT

A radio frequency module includes: a module substrate including a principal surface; a bump electrode that is disposed on the principal surface and configured as an external-connection terminal of the radio frequency module; a semiconductor IC that is disposed on the principal surface and includes a low-noise amplifier that amplifies a radio frequency reception signal; an under-fill material disposed in a gap between the semiconductor IC and the principal surface; and a surface mount device disposed on the principal surface, between the bump electrode and the semiconductor IC, wherein in a plan view of the module substrate, an outer edge of the under-fill material is located between an edge of the inductor and an edge of the semiconductor IC, the respective edges of the inductor and semiconductor IC oppose the bump electrode.

### CROSS REFERENCE TO RELATED APPLICATION

The present application is based on and claims priority to Japanese Patent Application No. 2019-233728 filed on Dec. 25, 2019. The entire disclosure of the above-identified application, including the specification, drawings and claims is incorporated herein by reference in its entirety.

### TECHNICAL FIELD

The present disclosure relates to a radio frequency module and a communication device.

### BACKGROUND

In a mobile communication device such as a mobile phone, the disposition and structure of circuit elements of a radio frequency front-end circuit are increasingly more complex with the progress particularly in multiband communications.

United States Patent Application Publication No. 2018/0226271 discloses a dual-sided, surface-mount radio frequency module capable of controlling the distribution of an under-fill material between one or more components and a packaging substrate. United States Patent Application Publication No. 2018/0226271 controls the flow of the under-fill material by, for example, a dam on the packaging substrate.

### SUMMARY

### Technical Problems

However, as recognized by the present inventor, United States Patent Application Publication No. 2018/0226271 requires an additional manufacturing process of forming a dam on the packaging substrate. Stated differently, an increased number of manufacturing processes is necessary to control the distribution of the under-fill material.

In view of the above, the present disclosure aims to provide a radio frequency module and a communication device capable of controlling the distribution of an under-fill material, while preventing an increase in the number of manufacturing processes.

### Solutions

The radio frequency module according to an aspect of the present disclosure includes: A radio frequency module includes: a module substrate including a principal surface; a bump electrode that is disposed on the principal surface and configured as an external-connection terminal of the radio frequency module; a semiconductor IC that is disposed on the principal surface and includes a low-noise amplifier that amplifies a radio frequency reception signal; an under-fill material disposed in a gap between the semiconductor IC and the principal surface; and a surface mount device disposed on the principal surface, between the bump electrode and the semiconductor IC, wherein in a plan view of the module substrate, an outer edge of the under-fill material is located between an edge of the inductor and an edge of the semiconductor IC, the respective edges of the inductor and semiconductor IC oppose the bump electrode.

### Advantageous Effects

The radio frequency module according to an aspect of the present disclosure is capable of controlling the distribution of an under-fill material, while preventing an increase in the number of manufacturing processes.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a diagram showing the circuit structure of the communication device according to an embodiment of the present disclosure.

FIG. 2 is a diagram showing the circuit structure of a matching circuit according to the embodiment.

FIG. 3 is a plan view of the radio frequency module (or RF front-end circuitry) according to the embodiment.

FIG. 4 is an enlarged view of the radio frequency module according to the embodiment.

FIG. 5 is a cross-sectional view of the radio frequency module according to the embodiment.

### DESCRIPTION OF EMBODIMENT

The following describes in detail the embodiment and a variation thereof according to the present disclosure with reference to the drawings. Note that the following embodiment and variation thereof show a comprehensive or specific example of the present disclosure. The numerical values, shapes, materials, structural elements, the arrangement and connection of the structural elements, etc. shown in the following embodiment and variation thereof are mere examples, and thus are not intended to limit the present disclosure.

Note that the drawings are schematic diagrams in which emphasis, omission, or ratio adjustment has been applied where necessary to illustrate the present disclosure. The drawings are thus not necessarily exact illustration of the present disclosure, and may illustrate shapes, positional relationships, and ratios differently from the actual ones. In the drawings, substantially the same structural elements are assigned the same reference marks, and their repetitive description may be omitted or simplified.

In the drawings, the X axis and the Y axis are orthogonal to each other on a plane that is parallel to a principal surface of a module substrate. Also, the Z axis is normal to a principal surface of the module substrate. The positive direction and the negative direction of the Z axis indicate the upward direction and the downward direction, respectively.

Also, terms used in the present disclosure have the meanings described below.

“connected” means not only the case where elements are directly connected via a connection terminal and/or a wiring conductor, but also the case where elements are electrically connected via another circuit element.

“directly connected” means that elements are directly connected via a connection terminal and/or a wiring conductor without being connected via another circuit element.

terms that represent the relation between elements (e.g., “parallel” and “vertical”), terms that represent the shape of an element (e.g., “rectangular”), and a range of numerical values indicate not only the exact meanings of the terms, but also substantially equivalent scopes of the terms. For example, such terms include the meaning of a few percent of error.

“in a plan view of a substrate” means a view of an object that is orthographically projected onto the XY plane and seen from the positive direction of the Z axis.

“C is located between A and B in a plan view of a substrate” means that, in a plan view of the substrate, a line that connects a point in A and a point in B passes through C.

### Embodiment

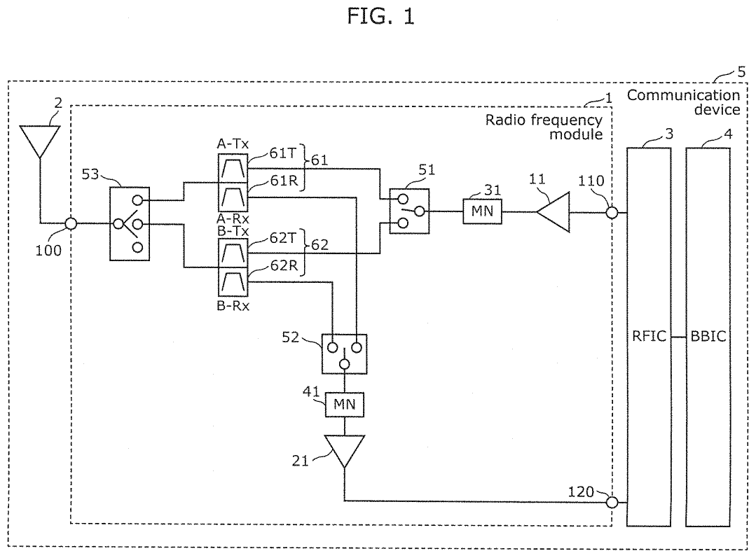

With reference to FIG. 1 through FIG. 5, the disclosed embodiments will be described.

### [1.1 Circuit Structures of Radio Frequency Module 1 and Communication Device 5]

The following describes the circuit structures of radio frequency module 1 and communication device 5 according to the present embodiment. FIG. 1 is a diagram showing the circuit structures of radio frequency module 1 and communication device 5 according to the present embodiment.

### [1.1.1 Circuit Structure of Communication Device 5]

With reference to FIG. 1, the circuit structure of communication device 5 will be specifically described. As shown in FIG. 1, communication device 5 includes radio frequency module 1, antenna 2, RFIC 3, and BBIC 4.

Radio frequency module 1 transfers a radio frequency signal between antenna 2 and RFIC 3. A detailed circuit structure of radio frequency module 1 will be described later.

Antenna 2 is connected to antenna connection terminal 100 of radio frequency module 1. Antenna 2 radiates a radio frequency signal outputted from radio frequency module 1. Antenna 2 also receives a radio frequency signal from outside and outputs the received radio frequency signal to radio frequency module 1.

RFIC 3 is an example of the signal processing circuit that processes a radio frequency signal that is to be transmitted or has been received by antenna 2. More specifically, RFIC 3 performs signal processing, such as down-conversion, on a radio frequency reception signal inputted via a reception signal path of radio frequency module 1, and outputs the resulting reception signal to BBIC 4. RFIC 3 also performs signal processing, such as up-conversion, on a transmission signal inputted from BBIC 4, and outputs the resulting radio frequency transmission signal to a transmission signal path of radio frequency module 1.

BBIC 4 is a baseband signal processing circuit that performs signal processing by use of an intermediate frequency band, the frequency of which is lower than that of a radio frequency signal transferred by radio frequency module 1. The signal processed by BBIC 4 is used, for example, as an image signal for image display, or as a sound signal for telephone conversation through a speaker.

RFIC 3 controls connections of switches 51 through 53 included in radio frequency module 1 on the basis of a communication band to be used. RFIC 3 also transfers, to radio frequency module 1, a control signal for adjusting the gain, etc. of power amplifier 11 of radio frequency module 1.

Note that communication device 5 according to the present embodiment may not include antenna 2 and BBIC 4. Stated differently, antenna 2 and BBIC 4 are not essential structural elements of the communication device according to the present disclosure.

### [1.1.2 Circuit Structure of Radio Frequency Module 1]

With reference to FIG. 1, the circuit structure of radio frequency module 1 will be specifically described. As shown in FIG. 1, radio frequency module 1 includes power amplifier 11, low-noise amplifier 21, matching circuits 31 and 41, switches 51 through 53, duplexers 61 and 62, antenna connection terminal 100, transmission input terminal 110, and reception output terminals 120.

Power amplifier 11 amplifies a radio frequency transmission signal inputted from transmission input terminal 110. For example, power amplifier 11 amplifies a radio frequency transmission signal in communication band A and/or communication band B.

Low-noise amplifier 21 amplifies a radio frequency reception signal and outputs the resulting radio frequency reception signal to reception output terminal 120. For example, low-noise amplifier 21 performs low-noise amplification on a radio frequency reception signal in communication band A and/or communication band B.

Duplexer 61 passes radio frequency signals in communication band A. Duplexer 61 transfers a transmission signal and a reception signal in communication band A by the frequency division duplex (FDD) method. Duplexer 61 includes transmission filter 61T and reception filter 61R.

Transmission filter 61T is connected between power amplifier 11 and antenna connection terminal 100. Transmission filter 61T passes a radio frequency signal in the transmission band in communication band A among radio frequency signals amplified by power amplifier 11.

Reception filter 61R is connected between low-noise amplifier 21 and antenna connection terminal 100. Reception filter 61R passes a radio frequency signal in the reception band in communication band A among radio frequency signals inputted from antenna connection terminal 100.

Duplexer 62 passes radio frequency signals in communication band B. Duplexer 62 transfers a transmission signal and a reception signal in communication band B by the FDD method. Duplexer 62 includes transmission filter 62T and reception filter 62R.

Transmission filter 62T is connected between power amplifier 11 and antenna connection terminal 100. Transmission filter 62T passes a radio frequency signal in the transmission band in communication band B among radio frequency signals amplified by power amplifier 11.

Reception filter 62R is connected between low-noise amplifier 21 and antenna connection terminal 100. Reception filter 62R passes a radio frequency signal in the reception band in communication band B among radio frequency signals inputted from antenna connection terminal 100.

Matching circuit 31 is connected between power amplifier 11 and transmission filters 61T and 62T. Matching circuit 31 is an impedance matching circuit that is directly connected to the output terminal of power amplifier 11. Matching circuit 31 matches the impedance between power amplifier 11 and transmission filters 61T and 62T.

Matching circuit 41 is connected between low-noise amplifier 21 and reception filters 61R and 62R. Matching circuit 41 is an impedance matching circuit that is directly connected to the input terminal of low-noise amplifier 21. Matching circuit 41 matches the impedance between low-noise amplifier 21 and reception filters 61R and 62R.

Switch 51 is connected between transmission filters 61T and 62T and power amplifier 11. More specifically, switch 51 includes a common terminal and two selection terminals. The common terminal of switch 51 is connected to power amplifier 11 via matching circuit 31. A first selection terminal, which is one of the two selection terminals of switch 51, is connected to transmission filter 61T, and a second selection terminal, which is the other of the two selection terminals of switch 51, is connected to transmission filter 62T. Having such connection structure, switch 51 switches between connecting the common terminal and the first selection terminal, and connecting the common terminal and the second selection terminal. Stated differently, switch 51 is a band selection switch that switches between connecting power amplifier 11 and transmission filter 61T, and connecting power amplifier 11 and transmission filter 62T. Switch 51 is implemented, for example, as a single pole double throw (SPDT) switch circuit.

Switch 52 is connected between reception filters 61R and 62R and low-noise amplifier 21. More specifically, switch 52 includes a common terminal and two selection terminals. The common terminal of switch 52 is connected to low-noise amplifier 21 via matching circuit 41. A first selection terminal, which is one of the two selection terminals of switch 52, is connected to reception filter 61R, and a second selection terminal, which is the other of the two selection terminals of switch 52, is connected to reception filter 62R. Having such connection structure, switch 52 switches between connecting the common terminal and the first selection terminal, and connecting the common terminal and the second selection terminal. Stated differently, switch 52 is an IN switch for a low-noise amplifier (LNA) that switches between connecting low-noise amplifier 21 and reception filter 61R, and connecting low-noise amplifier 21 and reception filter 62R. Switch 52 is implemented, for example, as a SPDT switch circuit.

Switch 53 is connected between antenna connection terminal 100 and duplexers 61 and 62. More specifically, switch 53 includes a common terminal and at least two selection terminals. The common terminal of switch 53 is connected to antenna connection terminal 100. A first selection terminal, which is one of the at least two selection terminals of switch 53, is connected to duplexer 61, and a second selection terminal, which is another one of the at least two selection terminals of switch 53, is connected to duplexer 62. Having such connection structure, switch 53 switches between connecting/disconnecting the common terminal and the first selection terminal, and connecting/disconnecting the common terminal and the second selection terminal. Stated differently, switch 53 is an antenna switch that switches between connecting/disconnecting antenna 2 and duplexer 61, and connecting/disconnecting antenna 2 and duplexer 62. Switch 53 is implemented, for example, as a multi-connection switch circuit.

Note that radio frequency module 1 may not include one or more of the circuit elements shown in FIG. 1. For example, radio frequency module 1 is simply required to include low-noise amplifier 21 and at least one of the other circuit elements (e.g., matching circuit 41), without needing to include the rest of the circuit elements.

The circuit structure of radio frequency module 1 is capable of FDD communications of a transmission signal and a reception signal, but the circuit structure of the radio frequency module according to the present disclosure is not limited to this example. For example, the radio frequency module according to the present disclosure may have a circuit structure capable of time division duplex (TDD) communications of a transmission signal and a reception signal, or may have a circuit structure capable of both FDD and TDD communications.

### [1.1.3 Circuit Structure of Matching Circuit 41]

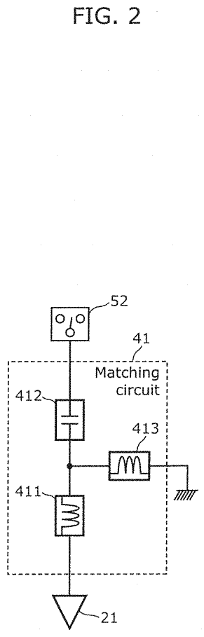

With reference to FIG. 2, the circuit structure of matching circuit 41 will be specifically described. FIG. 2 is diagram showing the circuit structure of the matching circuit according to the embodiment. As shown in FIG. 2, matching circuit 41 includes inductor 411, capacitor 412, and inductor 413.

Inductor 411 and capacitor 412 are connected in series between switch 52 and low-noise amplifier 21. Inductor 413 is connected between the ground and the node that is located between inductor 411 and capacitor 412.

Note that matching circuit 41 shown in FIG. 2 is an example, and thus the circuit structure of matching circuit 41 is not limited to this example. For example, matching circuit 41 may not include capacitor 412 and inductor 413.

### [1.2 Disposition of Circuit Components of Radio Frequency Module 1]

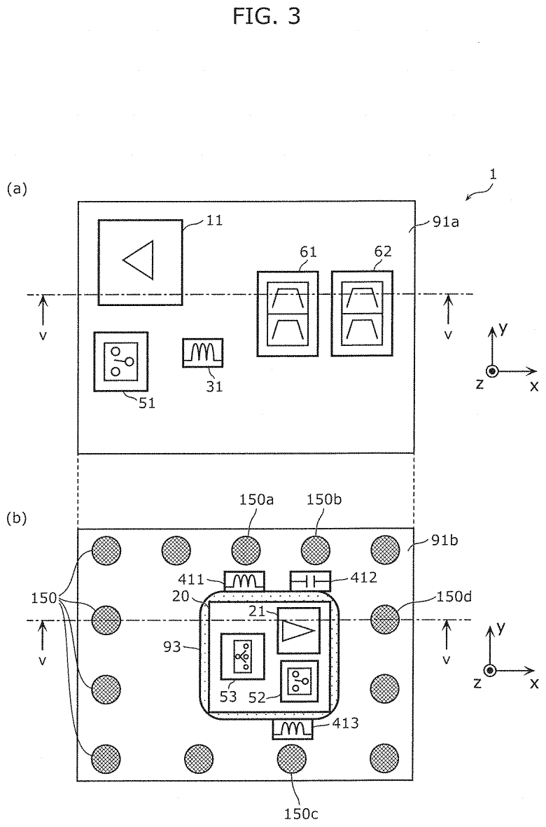

With reference to FIG. 3 through FIG. 5, the following specifically describes the disposition of the circuit components of radio frequency module 1 with the above structure.

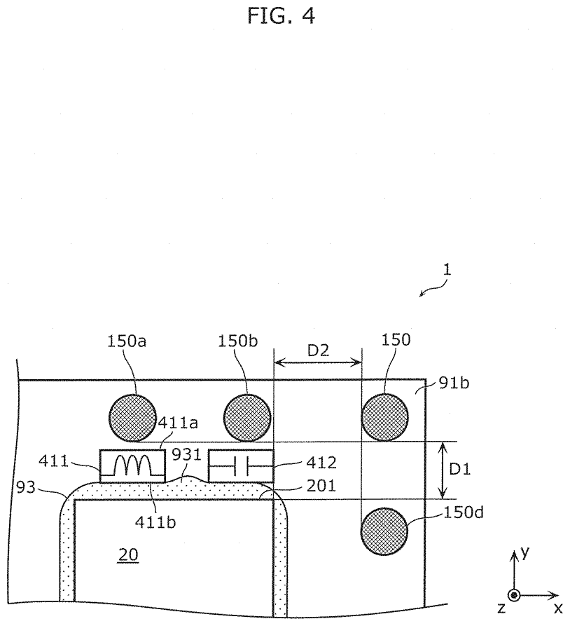

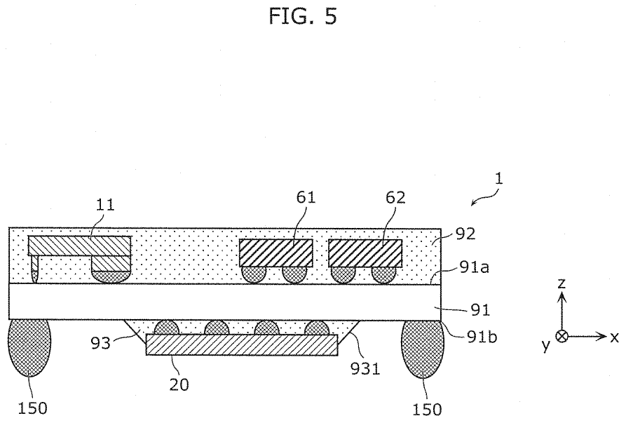

FIG. 3 is a plan view of radio frequency module 1 according to the embodiment. In FIG. 3, (a) is a view of principal surface 91a of module substrate 91 seen from the positive direction of the Z axis, and (b) is a perspective view of principal surface 91b of module substrate 91 seen from the positive direction of the Z axis. FIG. 4 is an enlarged view of radio frequency module 1 according to the embodiment. FIG. 4 shows an enlarged view of the peripheral region of inductor 411 and capacitor 412. FIG. 5 is a cross-sectional view of radio frequency module 1 according to the embodiment. FIG. 5 shows a cross-section of radio frequency module 1 cut along v-v line shown in FIG. 3.

As shown in FIG. 3 through FIG. 5, radio frequency module 1 further includes module substrate 91, resin member 92, under-fill material 93, and a plurality of bump electrodes 150, in addition to the circuit components that incorporate the circuit elements shown in FIG. 1. Note that FIG. 3 omits the illustration of resin member 92 to illustrate the circuit components.

Module substrate 91 includes principal surface 91a and principal surface 91b on opposite sides of module substrate 91. Non-limiting examples of module substrate 91 to be used include a printed circuit board (PCB), a low temperature co-fired ceramics (LTCC) substrate, and a multilayered resin substrate.

Principal surface 91a, which is an example of the second principal surface, is also referred to as an upper surface or a surface. As shown in (a) in FIG. 3, disposed on principal surface 91a are power amplifier 11, matching circuit 31, switch 51, and duplexers 61 and 62.

Non-limiting examples of duplexers 61 and 62 include an acoustic wave filter utilizing surface acoustic wave (SAW), an acoustic wave filter utilizing bulk acoustic wave (BAW), an LC resonant filter, and a dielectric filter, or may be any combination of these filters.

Principal surface 91b, which is an example of the first principal surface, is also referred to as a lower surface or a back surface. As shown in (b) in FIG. 3, disposed on principal surface 91b are: low-noise amplifier 21; inductor 411, capacitor 412, and inductor 413 included in matching circuit 41; and switches 52 and 53.

Low-noise amplifier 21, and switches 52 and 53 are incorporated in semiconductor integrated circuit (IC) 20 disposed on principal surface 91b. As shown in FIG. 3, semiconductor IC 20 has a rectangular shape in a plan view of module substrate 91.

Semiconductor IC 20 has, for example, a complementary metal oxide semiconductor (CMOS) structure. More specifically, semiconductor IC 20 is fabricated by a silicon on insulator (SOI) process. This enables a low-cost manufacture of semiconductor IC 20. Note that semiconductor IC 20 may include at least one of GaAs, SiGe, or GaN. This enables the output of a radio frequency signal having high quality amplification properties and noise characteristics. Note that semiconductor IC 20 may further incorporate switch 51.

Inductor 411, capacitor 412, and inductor 413 are implemented as surface mount devices (SMDs). SMDs are electronic components that are mounted on a substrate surface. Non-limiting examples of inductor 411, capacitor 412, and inductor 413 include integrated passive devices (IPDs).

As shown in FIG. 3, each of inductor 411, capacitor 412, and inductor 413 is disposed between bump electrode 150 and semiconductor IC 20. More specifically, inductor 411 is disposed on principal surface 91b, between bump electrode 150a and semiconductor IC 20. Capacitor 412 is disposed on principal surface 91b, between bump electrode 150b and semiconductor IC 20. Inductor 413 is disposed on principal surface 91b, between bump electrode 150c and semiconductor IC 20. Note that no SMD is disposed on principal surface 91b, between bump electrode 150d and semiconductor IC 20.

As shown in FIG. 3, each of inductor 411, capacitor 412, and inductor 413 has a rectangular shape in a plan view of module substrate 91. As shown in FIG. 4, for example, inductor 411 has edge 411a (first edge) opposing bump electrode 150a and edge 411b (second edge) opposing semiconductor IC 20. Capacitor 412 and inductor 413 also have edges as with inductor 411.

A plurality of bump electrodes 150 are disposed on principal surface 91b of module substrate 91 to be implemented as external-connection terminals of radio frequency module 1. A plurality of bump electrodes 150 include bump electrodes 150a, 150b, 150c, and 150d. Each of bump electrodes 150a, 150b, and 150c is an example of the first bump electrode, and 150d is an example of the second bump electrode. Each of bump electrodes 150 protrudes through principal surface 91b. The ends of bump electrodes 150 protruding through principal surface 91b are connected to an input and output terminal or a ground electrode, and so forth on the mother board that is disposed in the negative direction of the Z axis of radio frequency module 1. Non-limiting example structures of a plurality of bump electrodes 150 to be used include ball grid array (BGA).

Resin member 92 is disposed on principal surface 91a of module substrate 91, and covers the circuit components on principal surface 91a. Resin member 92 is capable of ensuring the reliability of the circuit components disposed on principal surface 91a, such as their mechanical strength and humidity resistance. Note that radio frequency module 1 may not include resin member 92. Stated differently, resin member 92 is not an essential structural element of the radio frequency module according to the present disclosure.

Under-fill material 93 is filled between semiconductor IC 20 and principal surface 91b. Under-fill material 93 is capable of ensuring the reliability of semiconductor IC 20 such as its drop impact resistance and corrosion resistance. Non-limiting examples of under-fill material 93 to be used include encapsulating resin, epoxy resin, polyurethane resin, silicone resin, and polyester resin, or any combination of these materials.

In a manufacturing process, under-fill material 93 is injected into the gap between semiconductor IC 20 and principal surface 91b, after semiconductor IC 20, inductor 411, and so forth are mounted onto principal surface 91b. Under-fill material 93 having been injected spreads across the gap, using a capillary phenomenon, and partially flows out of the gap. After this, under-fill material 93 cures. Here, the process of forming a plurality of bump electrodes 150 on principal surface 91b may be performed either before or after the process of injecting under-fill material 93. Here, a portion of under-fill material 93 having flowed out of the gap is referred to as overflow portion 931.

With reference to FIG. 4, the following describes the positional relation between overflow portion 931 of under-fill material 93 and inductor 411. Note that the following omits the description of capacitor 412 and inductor 413 because the positional relations thereof with overflow portion 931 are the same as that of inductor 411.

In a plan view of module substrate 91, overflow portion 931 of under-fill material 93 reaches a position between edge 411a of inductor 411 and edge 201 of semiconductor IC 20. Stated differently, in a plan view of module substrate 91, the outer edge of under-fill material 93 is located between edge 411a of inductor 411 and edge 201 of semiconductor IC 20.

More specifically, in a plan view of module substrate 91, overflow portion 931 reaches edge 411b of inductor 411. In other words, in a plan view of module substrate 91, the outer edge of under-fill material 93 is located between edge 411a and edge 411b of inductor 411.

In the present embodiment, SMDs are disposed between semiconductor IC 20 and the first bump electrodes, which are some of a plurality of bump electrodes 150, but no SMD is disposed between semiconductor IC 20 and the second bump electrode, which is the rest of a plurality of bump electrodes 150. In this case, the distance between each of the first bump electrodes and semiconductor IC 20 is smaller than the distance between the second bump electrode and semiconductor IC 20.

For example, inductor 411, capacitor 412, and inductor 413 are disposed on principal surface 91b, between semiconductor IC 20 and bump electrodes 150a, 150b, and 150c, respectively. Meanwhile, no SMD is disposed between semiconductor IC 20 and bump electrode 150d. In this case, distance D1 between semiconductor IC 20 and bump electrode 150a is smaller than distance D2 between semiconductor IC 20 and bump electrode 150d. Similarly, the distance between semiconductor IC 20 and each of bump electrodes 150b and 150c is smaller than the distance between semiconductor IC 20 and bump electrode 150d.

Stated differently, SMDs are disposed between semiconductor IC 20 and the first bump electrodes, which are some of a plurality of bump electrodes 150 located closer to semiconductor IC 20, but no SMD is disposed between semiconductor IC 20 and the second bump electrode, which is more distantly located from semiconductor IC 20 than the first bump electrodes.

Here, the distance between two objects on principal surface 91b of module substrate 91 means the shortest distance between the outer edges of the two objects. Stated differently, the distance between the two objects is the length of the shortest line among a plurality of lines that connect the outer edge of one of the objects and the outer edge of the other of the objects.

Note that in the present embodiment, inductor 413 is disposed distantly from inductor 411 and capacitor 412, but inductor 413 may be disposed close to inductor 411 and capacitor 412. In this case, another circuit component is simply required to be disposed in the position of inductor 413 shown in FIG. 3.

Note that radio frequency module 1 may include a shield electrode layer (not illustrated) that covers the upper and side surfaces of resin member 92. Set at the ground potential, the shield electrode layer prevents the entry of exogenous noise into the circuit components included in radio frequency module 1.

### [1.3 Effects, Etc.]

As described above, radio frequency module 1 according to the present embodiment includes: module substrate 91 that includes principal surface 91b; a first bump electrode (e.g., bump electrode 150a) that is disposed on principal surface 91b and implemented as an external-connection terminal of radio frequency module 1; semiconductor IC 20 that is disposed on principal surface 91b and includes low-noise amplifier 21 that amplifies a radio frequency reception signal; under-fill material 93 that is filled in the gap between semiconductor IC 20 and principal surface 91b; and an SMD (e.g., inductor 411) that is disposed on principal surface 91b, between the first bump electrode and semiconductor IC 20. In radio frequency module 1, in a plan view of module substrate 91, an outer edge of under-fill material 93 is located between a first edge (e.g., edge 411a) of the SMD and an edge (e.g., edge 201) of semiconductor IC 20. Here, each of the first edge and the edge is opposite to the first bump electrode.

Also, communication device 5 according to the present embodiment includes: RFIC 3 that process a radio frequency signal that is to be transmitted or has been received by antenna 2; and radio frequency module 1 that transfers the radio frequency signal between antenna 2 and RFIC 3.

This structure enables an SMD to be disposed on principal surface 91b, between the first bump electrode and semiconductor IC 20. Such SMD stems the distribution of under-fill material 93 that has flowed out of the gap in a manufacturing process, thus preventing under-fill material 93 from reaching the position of the first bump electrode. Consequently, the above structure prevents the degradation caused by under-fill material 93 in the bonding of the first bump electrode to module substrate 91 or the mother board. This structure also enables the use of an SMD for stemming the flow of under-fill material 93. This structure further enables the use of a circuit component of the radio frequency circuit as an SMD, thus eliminating a process of forming a dam on module substrate 91 only for controlling the distribution of under-fill material 93. An increase in the number of manufacturing processes is thus prevented.

In radio frequency module 1 according to the present embodiment, for example, in a plan view of module substrate 91, the outer edge of under-fill material 93 may be located between the first edge (e.g., edge 411a) and a second edge (e.g., edge 411b) of the SMD. Here, the second edge is opposite to semiconductor IC 20.

This structure enables the SMD to effectively stem the distribution of under-fill material 93 under a condition in which under-fill material 93 flows toward the SMD.

Radio frequency module 1 according to the present embodiment may further include, for example, a second bump electrode (e.g., bump electrode 150d) that is disposed on principal surface 91b and implemented as an external-connection terminal of radio frequency module 1. In radio frequency module 1, no SMD may be disposed on principal surface 91b, between the second bump electrode and semiconductor IC 20, and in a plan view of module substrate 91, the distance between the first bump electrode and semiconductor IC 20 may be smaller than the distance between the second bump electrode and semiconductor IC 20.

This structure enables an SMD to be disposed between semiconductor IC 20 and a bump electrode that is more closely located to semiconductor IC 20. This thus more effectively prevents under-fill material 93 from reaching the position of the bump electrode.

In radio frequency module 1 according to the present embodiment, for example, the SMD may be capacitor 412 and/or inductor 413 included in matching circuit 41 connected to the input terminal of low-noise amplifier 21.

This structure enables capacitor 412 and/or inductor 413 to be disposed close to low-noise amplifier 21, thus reducing the wiring length between low-noise amplifier 21 and matching circuit 41. Consequently, mismatching loss caused by wiring loss and wiring variation is reduced, thereby improving the electrical characteristics (e.g., noise figure (NF), gain characteristics) of radio frequency module 1.

In radio frequency module 1 according to the present embodiment, for example, the SMD may be inductor 411 included in matching circuit 41 connected to the input terminal of low-noise amplifier 21.

This structure enables inductor 411 to be disposed close to low-noise amplifier 21, thus reducing the wiring length between low-noise amplifier 21 and matching circuit 41. Consequently, mismatching loss caused by wiring loss and wiring variation is reduced, thereby improving the electrical characteristics (e.g., noise figure (NF), gain characteristics) of radio frequency module 1.

In radio frequency module 1 according to the present embodiment, for example, the SMD may be an integrated passive device.

This structure reduces the height of SMDs disposed on principal surface 91b, contributing to the reduction in the entire height of radio frequency module 1.

In radio frequency module 1 according to the present embodiment, for example, module substrate 91 may include principal surface 91a opposing principal surface 91b, and radio frequency module 1 may further include power amplifier 11 that is disposed on principal surface 91a and amplifies a radio frequency transmission signal.

This structure enables circuit components to be disposed on both surfaces of module substrate 91, contributing to the downsizing of radio frequency module 1. This structure also enables power amplifier 11 and low-noise amplifier 21 to be disposed on different surfaces, thus improving the isolation characteristics between a transmission circuit and a reception circuit.

### Variation

The radio frequency module and the communication device according to the present disclosure have been described above, using the embodiment, but the radio frequency module and the communication device according to the present disclosure are not limited to such embodiment. The present disclosure also includes: another embodiment achieved by freely combining structural elements in the embodiment; variations achieved by making various modifications to the embodiment that can be conceived by those skilled in the art without departing from the essence of the present disclosure; and various devices that incorporate the radio frequency module and the communication device described above.

For example, in the radio frequency module and the communication device according to the foregoing embodiment, another circuit element, wiring, and so forth may be present in a path that connects each circuit element and a signal path disclosed in the drawings. In the foregoing embodiment, for example, an impedance matching circuit may be connected between duplexer 61 and switch 53, and/or between duplexer 62 and switch 53.

Note that the shape and disposition of each component, as well as the shape, number, and disposition of each bump electrode in the foregoing embodiment are mere examples, and thus the present disclosure is not limited to these examples. For example, switch 51 may be disposed on principal surface 91b, and may be incorporated in semiconductor IC 20.

Also, in the foregoing embodiment, inductor 411, capacitor 412, and inductor 413 included in matching circuit 41 are used as SMDs disposed on principal surface 91b of module substrate 91, but the present disclosure is not limited to this configuration. Matching circuit 31 and/or switch 51, for example, may be disposed on principal surface 91b of module substrate 91 as SMDs. Also, components for another communication band or chip components that are not present on a radio frequency signal path (e.g., chip inductor that is connected to the ground at both ends) may be used as SMDs.

Note that in the foregoing embodiment, SMDs are disposed between semiconductor IC 20 and some of a plurality of bump electrodes 150, but the present disclosure is not limited to this configuration. An SMD may be disposed, for example, between semiconductor IC 20 and each of bump electrodes 150. Also, an SMD may be disposed, for example, between semiconductor IC 20 and only one of bump electrodes 150 that is most closely located to semiconductor IC 20.

Although only an exemplary embodiment of the present disclosure has been described in detail above, those skilled in the art will readily appreciate that many modifications are possible in the exemplary embodiment without materially departing from the novel teachings and advantages of the present disclosure. Accordingly, all such modifications are intended to be included within the scope of the present disclosure.

### INDUSTRIAL APPLICABILITY

The present disclosure is widely applicable for use in a communication device (e.g., mobile phone) as a radio frequency module that is placed at the front-end portion.

1. A radio frequency module, comprising:
a substrate including a first principal surface;
a first bump electrode disposed on the first principal surface and configured as an external-connection terminal of the radio frequency module;
a semiconductor integrated circuit disposed on the first principal surface and including a low-noise amplifier configured to amplify a radio frequency reception signal;
an under-fill material disposed in a gap between the semiconductor integrated circuit and the first principal surface; and
a surface mount device disposed on the first principal surface, between the first bump electrode and the semiconductor integrated circuit,
wherein in a plan view of the substrate, an outer edge of the under-fill material is located between a first edge of the surface mount device and an edge of the semiconductor integrated circuit, the first edge of the surface mount device and the edge of the semiconductor integrated circuit each opposing the first bump electrode.

2. The radio frequency module according to claim 1,
wherein in the plan view of the substrate, the outer edge of the under-fill material is located between the first edge of the surface mount device and a second edge of the surface mount device, the second edge of the surface mount device opposing the edge of the semiconductor integrated circuit.

3. The radio frequency module according to claim 1, further comprising:
a second bump electrode disposed on the first principal surface and configured as another external-connection terminal of the radio frequency module,
wherein no surface mount device is disposed on the first principal surface between the second bump electrode and the edge of the semiconductor integrated circuit, and
in the plan view of the substrate, a distance between the first bump electrode and the edge of the semiconductor integrated circuit is smaller than a distance between the second bump electrode and the edge of the semiconductor integrated circuit.

4. The radio frequency module according to claim 1,
wherein the surface mount device is an inductor included in a matching circuit connected to an input terminal of the low-noise amplifier.

5. The radio frequency module according to claim 4,
wherein the surface mount device is an integrated passive device.

6. The radio frequency module according to claim 1,
wherein the surface mount device is a capacitor included in a matching circuit connected to an input terminal of the low-noise amplifier.

7. The radio frequency module according to claim 1,
wherein the substrate includes a second principal surface opposing the first principal surface, and
the radio frequency module further includes a power amplifier disposed on the second principal surface that is configured to amplify a radio frequency transmission signal.

8. A communication device, comprising:
a signal processing circuit configured to process a radio frequency signal that is to be transmitted or has been received by an antenna; and
the radio frequency module configured to transfer the radio frequency signal between the antenna and the signal processing circuit, the radio frequency module including
a substrate including a first principal surface,
a first bump electrode disposed on the first principal surface and configured as an external-connection terminal of the radio frequency module,
a semiconductor integrated circuit disposed on the first principal surface and including a low-noise amplifier configured to amplify a radio frequency reception signal,
an under-fill material disposed in a gap between the semiconductor integrated circuit and the first principal surface, and
a surface mount device disposed on the first principal surface, between the first bump electrode and the semiconductor integrated circuit,
wherein in a plan view of the substrate, an outer edge of the under-fill material is located between a first edge of the surface mount device and an edge of the semiconductor integrated circuit, the first edge of the surface mount device and the edge of the semiconductor integrated circuit each opposing the first bump electrode.

9. The communication device according to claim 8,
wherein in the plan view of the substrate, the outer edge of the under-fill material is located between the first edge of the surface mount device and a second edge of the surface mount device, the second edge of the surface mount device opposing the edge of the semiconductor integrated circuit.

10. The communication device according to claim 8, wherein the radio frequency module further comprising:
a second bump electrode disposed on the first principal surface and configured as another external-connection terminal of the radio frequency module,
wherein no surface mount device is disposed on the first principal surface between the second bump electrode and the edge of the semiconductor integrated circuit, and
in the plan view of the substrate, a distance between the first bump electrode and the edge of the semiconductor integrated circuit is smaller than a distance between the second bump electrode and the edge of the semiconductor integrated circuit.

11. The communication device according to claim 8,
wherein the surface mount device is an inductor included in a matching circuit connected to an input terminal of the low-noise amplifier.

12. The communication device according to claim 11,
wherein the surface mount device is an integrated passive device.

13. The communication device according to claim 8,
wherein the surface mount device is a capacitor included in a matching circuit connected to an input terminal of the low-noise amplifier.

14. The communication device according to claim 8,
wherein the substrate includes a second principal surface opposing the first principal surface, and
the radio frequency module further includes a power amplifier disposed on the second principal surface that is configured to amplify a radio frequency transmission signal.

15. A radio frequency module comprising:
a substrate including a first principal surface,
a first bump electrode disposed on the first principal surface and configured as an external-connection terminal of the radio frequency module,
a semiconductor integrated circuit disposed on the first principal surface and including a low-noise amplifier configured to amplify a radio frequency reception signal,
an under-fill material disposed in a gap between the semiconductor integrated circuit and the first principal surface, and
a surface mount device disposed on the first principal surface, between the first bump electrode and the semiconductor integrated circuit, and
means for controlling a distribution of underfill material outside of the gap.

16. The radio frequency module according to claim 15,
wherein the means for controlling includes means for stemming the distribution of the under-fill material from reaching the first bump electrode.

17. The radio frequency module according to claim 15, further comprising:
a second bump electrode disposed on the first principal surface and configured as another external-connection terminal of the radio frequency module,
wherein no surface mount device is disposed on the first principal surface between the second bump electrode and the semiconductor integrated circuit, and
in a plan view of the substrate, a distance between the first bump electrode and a closest edge of the semiconductor integrated circuit is smaller than a distance between the second bump electrode and the closest edge of the semiconductor integrated circuit.

18. The radio frequency module according to claim 15,
wherein the surface mount device is an inductor included in a matching circuit connected to an input terminal of the low-noise amplifier.

19. The radio frequency module according to claim 18,
wherein the surface mount device is an integrated passive device.

20. The radio frequency module according to claim 15,
wherein the surface mount device is a capacitor included in a matching circuit connected to an input terminal of the low-noise amplifier.
